(19) United States
(12) Patent Application Publication
(10) Pub. No.: US 2011/0249695 A1
(43) Pub. Date: Oct. 13, 2011

(54) Optically Pumped Laser

(76) Inventors: Dmitri Vladislavovich Kuksenkov, Big Flats, NY (US); Dmitry Sizov, Corning, NY (US); James Andrew West, Painted Post, NY (US)

(21) Appl. No.: 12/759,058

(22) Filed: Apr. 13, 2010

(51) Int. Cl. H01S 5/34; H01S 3/091

(52) U.S. Cl. 372/45.01; 372/70; 977/755

(57) ABSTRACT

Concepts of the present disclosure may be employed to optimize optical pumping and ensure high modal gain in the active region of an optically pumped laser source by establishing an optical coupling gap such that the pump waveguide mode field overlaps the active gain region associated with the signal waveguide. The optical coupling gap is tailored to be sufficiently large to ensure that a significant active gain region length is required for absorption and sufficiently small to ensure that the pump waveguide mode field P overlaps the active gain region. In accordance with one embodiment of the present disclosure, the pump waveguide core is displaced from the signal waveguide core by an optical coupling gap g in a lateral direction that is approximately perpendicular to the optical pumping axis. A decayed intensity portion of the pump waveguide mode field extends into the active gain region to optically pump the active gain region and form an optical signal propagating along the longitudinal optical signal axis of the signal waveguide core.

### BACKGROUND

The present disclosure relates to lasers and, more particularly, to optically pumped lasers designed to address design challenges associated with pump absorption in the active region of the laser.

### BRIEF SUMMARY

Although the concepts of the present disclosure are not limited to green laser sources, in the context of optically pumped green laser sources, the present inventors have recognized that existing blue laser diodes can be convenient optical pump sources but can also be problematic to utilize in a green laser source. Specifically, considering a laser structure consisting of 3-nm thick InGaN quantum wells (QWs) embedded in an InGaN waveguide layer, if such a structure is side-pumped with a blue laser diode beam, then only about 3% of the pump light will be absorbed in a single QW of the active region because the absorption coefficient for blue light in In_{0.25}Ga_{0.75}N is only about 1×10⁵ cm⁻¹. Even if the structure contains 10 quantum wells and the pump light is double-passed, only about 46% of the pump light will ultimately be absorbed. The resulting laser would be inefficient and would require a relatively high pump power to produce the carrier density needed to reach the lasing threshold. Alternatively, if the structure is end-pumped, assuming an optical confinement factor as low as 0.01, the absorption length for the pump light will be about 0.001 cm, which is far shorter than what would be needed to create a working laser. The concepts presented herein relate to optical pump configurations for lasers including, but not limited to, blue-pumped green laser sources and, more particularly, blue-pumped green lasers based on InGaN multi quantum wells (MQW).

Concepts of the present disclosure may be employed to optimize optical pumping and ensure high modal gain in the active region of an optically pumped laser source by establishing an optical coupling gap such that the pump waveguide mode field overlaps the active gain region associated with the signal waveguide. The optical coupling gap is tailored to be sufficiently large to ensure that a significant active gain region length is required for absorption and sufficiently small to ensure that the pump waveguide mode field P overlaps the active gain region. In accordance with one embodiment of the present disclosure, a laser comprising a pump waveguide core, a signal waveguide core, and an active gain region is provided. The pump waveguide core is oriented along a longitudinal optical pumping axis and is surrounded by cladding material characterized by an index of refraction that is lower than that of the pump waveguide core at a given pump wavelength. The signal waveguide core is oriented along a longitudinal optical signal axis and is surrounded by cladding material characterized by an index of refraction that is lower than that of the signal waveguide core at a given signal wavelength. The optical pumping axis is approximately parallel to the longitudinal optical signal axis and the pump waveguide core is displaced from the signal waveguide core by an optical coupling gap g in a lateral direction that is approximately perpendicular to the optical pumping axis. The signal waveguide core, the pump waveguide core, the surrounding cladding materials, and the optical coupling gap g are configured such that pump radiation propagating along the longitudinal optical pumping axis is characterized by a pump waveguide mode field comprising a decayed intensity portion, at least part of which extends into the active gain region to optically pump the active gain region and form an optical signal propagating along the longitudinal optical signal axis of the signal waveguide core.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 is a schematic illustration of a longitudinally-pumped laser structure;

FIGS. 2-4 are more detailed schematic illustrations of some alternative longitudinally-pumped laser structures; and

FIGS. 5 and 6, which illustrate the refractive index and normalized mode field profiles of a semiconductor laser, present two contemplated scenarios for mode field overlap in a laser structure according to the present invention.

### DETAILED DESCRIPTION

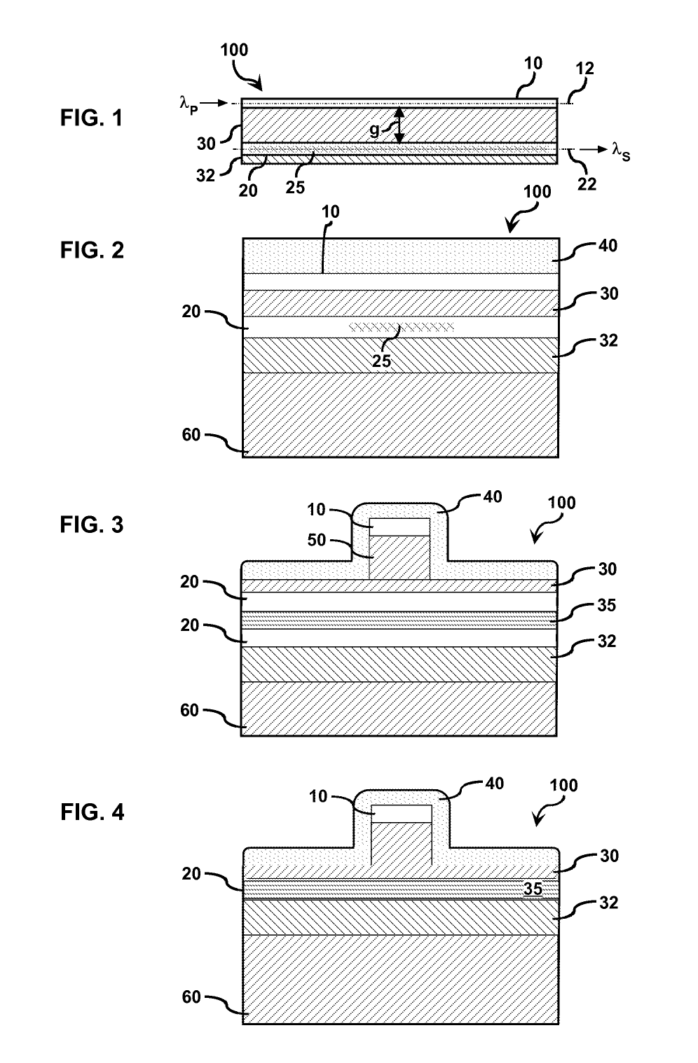

Referring initially to FIG. 1, a laser 100 is provided comprising a pump waveguide core 10, a signal waveguide core 20, an active gain region 25, and associated waveguide cladding material 30, 32. FIG. 1 illustrates the laser 100 along the longitudinal dimension of the device, while FIGS. 2-4, described in further detail below, are taken along a cross section of the device perpendicular to a longitudinal dimension of the device. As is clearly illustrated in FIG. 1, the pump waveguide core 10 is oriented along a longitudinal optical pumping axis 12 and is at least partially surrounded by cladding material characterized by an index of refraction that is lower than that of the pump waveguide core 10 at a given pump wavelength λ_{P}. Similarly, the signal waveguide core 20 is oriented along a longitudinal optical signal axis 22 and is also at least partially surrounded by cladding material. The signal waveguide cladding comprises material that is characterized by an index of refraction that is lower than a material of the signal waveguide core 20 at a given signal wavelength λ_{S}. FIG. 1 omits some of the laser structure for clarity but those familiar with waveguide technology will recognize that means should be provided for transverse confinement of the pump and signal radiation propagating along the optical pumping and signal axes 12, 22.

As is illustrated in FIG. 2, the cladding material for the pump waveguide core 10 can be provided in the form of a cap layer 40 and a cladding layer 30 that functions as a spacer layer between the pump waveguide core 10 and the signal waveguide core 20. It is contemplated that these layers may be integrated with other layers of the laser 100, omitted, further subdivided, or provided in a variety of alternative configurations. Suitable cladding materials include, but are not limited to, solid cladding materials, such as GaN, InGaN, and AlGaN, air, or solid cladding materials incorporating air. In the embodiment illustrated in FIG. 2, the signal waveguide core cladding material is provided in the form of cladding material 30, 32.

As is illustrated schematically in FIG. 1, the optical pumping axis 12 is approximately parallel to the longitudinal optical signal axis 22 and the pump waveguide core 10 is displaced from the signal waveguide core 20 by an optical coupling gap g in a lateral direction that is approximately perpendicular to the optical pumping axis 12. The pump radiation λ_{P} can be electrically or optically generated in the pump waveguide core 10 or can be generated elsewhere and be carried by the pump waveguide core 10. In either case, the pump radiation λ_{P} provides energy to the active region such that the active region becomes capable of providing optical gain and supports the formation of an optical signal λ_{S} propagating along the longitudinal optical signal axis 22, i.e., the active gain region 25 is optically pumped.

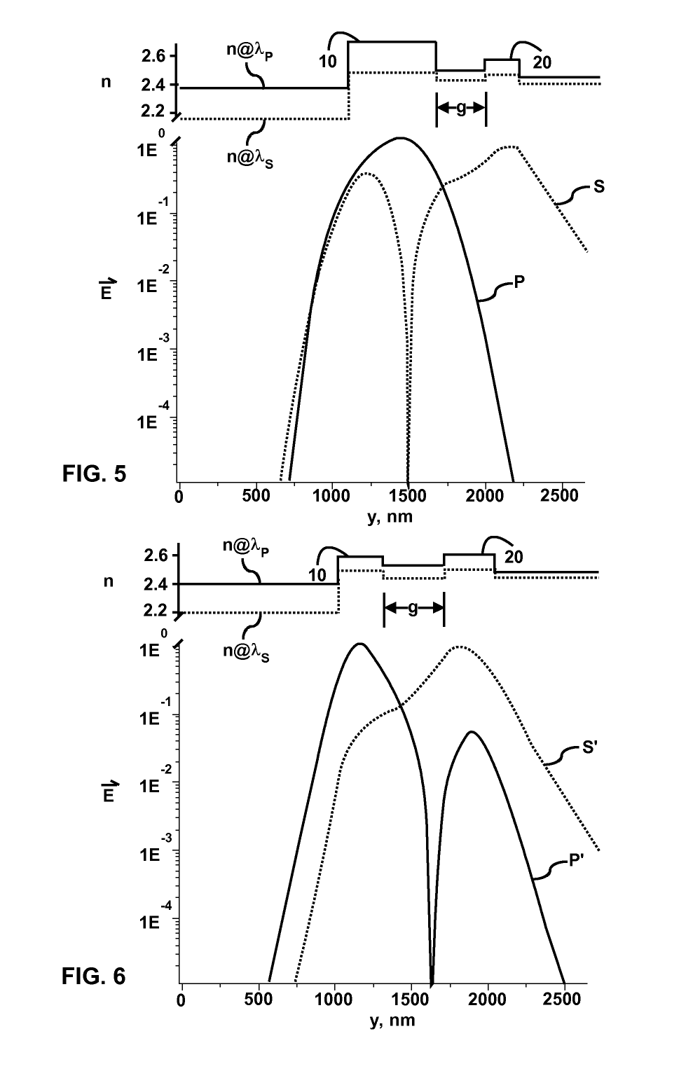

The pump waveguide core 10, the signal waveguide core 20, the surrounding cladding materials, and the optical coupling gap g are configured such that pump radiation λ_{P} propagating along the longitudinal optical pumping axis 12 is characterized by a pump waveguide mode field that overlaps the active gain region 25. The nature of this overlap is described in further detail herein with reference to FIGS. 5 and 6.

As is illustrated in FIGS. 3 and 4, the pump waveguide core cladding material can be provided in the form of a cap layer 40, cladding layer 30, and a spacer layer 50 that may be formed as part of the cladding layer 30 (see FIG. 4) or formed separately from the cladding layer 30 (see FIG. 3). In addition, the embodiments illustrated in FIGS. 3 and 4 provide the aforementioned active gain region in the form of a quantum well (QW) or multiple quantum well (MQW) active region 35 of a semiconductor laser. In FIG. 3, the MQW active region 35 is embedded between two waveguide cores 20 and the MQW active region 35, the compound waveguide cores 20, and the associated cladding material are formed as a multi-layered structure over the laser substrate 60. The compound signal waveguide cores 20 guide the stimulated emission of photons from the QW or MQW active region 35 while the associated cladding material promotes propagation of the emitted photons in the compound signal waveguide core.

In FIG. 4, the laser 100 also comprises a pump waveguide core 10, a signal waveguide core 20, and a QW or MQW active region 35. Although the specific structure and function of the MQW active region 35 is beyond the scope of the present disclosure and can be gleaned from a variety of publications on the subject, for the purposes of illustration, it may be helpful to note that QW or MQW active region 35 generally comprises a plurality of quantum wells and intervening barrier layers. As is illustrated in FIG. 4, the MQW active region 35 can be configured to also function as a signal waveguide core 20.

FIGS. 5 and 6, which illustrate the refractive index and normalized mode field profiles of the laser 100, present two contemplated scenarios for the aforementioned overlap of the active gain region by the mode field of the pump waveguide core 10. Specifically, in FIG. 5, the refractive index n of the pump waveguide core 10 is greater than the refractive index n of the signal waveguide core 20, at the pump wavelength λ_{P}. Accordingly, the pump waveguide core 10, the signal waveguide core 20, and the associated cladding materials are configured such that the intensity of the pump waveguide mode field P decays because of total internal reflection at the various refractive index interfaces of the structure but extends into the active gain region associated with the signal waveguide core 20. FIG. 5 also illustrates the signal waveguide mode field S. It is to be understood that the pumping waveguide core, pumping waveguide cladding, signal waveguide core and signal waveguide cladding in the scope of present invention may consist of multiple layers or superlattices. If these layers are much thinner than the pumping or signal wavelength, i.e., if the thicknesses are on the order of several nanometers, then the term “refractive index” refers to an average index of refraction of such layers.

The pump waveguide mode field P illustrated in FIG. 5 is characterized by an intensity maximum that lies outside of the active region associated with the signal waveguide core 20. FIG. 5 also shows that the pump waveguide mode field is further characterized by an exponentially decayed intensity portion. For the purposes of describing and defining the present invention, it is noted that reference herein to an exponentially decayed intensity portion is to be read broadly to cover the case illustrated in FIG. 5, where the pump signal P decays exponentially as it approaches the active gain region associated with the signal waveguide core 20, the case illustrated in FIG. 6, where the pump waveguide mode field P′ comprises a major intensity peak that lies outside of the active gain region associated with the signal waveguide core 20 and a and a minor intensity peak that lies along the decayed intensity portion of the mode field, or any case where the intensity trends exponentially lower as it approaches the active gain region.

A sufficiently large part of the decayed intensity portion extends into the active gain region associated with the signal waveguide core 20 to optically pump the active gain region and enable optical gain and formation of the optical signal λ_{S} in the active gain region. The decayed intensity portion is at least one, preferably between two and four, orders of magnitude less than the intensity maximum that lies outside of the active gain region. In this manner, because the magnitude of the decayed intensity portion is so much lower than the intensity maximum it becomes possible to distribute pump absorption along the length of the optical signal axis 22 in the active gain region associated with the signal waveguide core 20. More specifically, it is contemplated that the optical coupling gap g can be tailored to be sufficiently large to ensure that at least approximately 100 μm of the active gain region length is required for absorption of a majority of the pump waveguide mode field P and sufficiently small to ensure that the pump waveguide mode field P overlaps the active gain region associated with the signal waveguide core 20. In contrast, in the case of an end pumped semiconductor laser, for example, to enable a blue-pumped green laser based on InGaN MQW, given the absorption coefficient of 1×10⁵ cm⁻¹ for blue light in In_{0.25}Ga_{0.75}N and an optical confinement factor as low as 0.01, the absorption length for the pump light would be 1/(0.01)(1×10⁵ cm⁻¹)=0.001 cm (10 μm), which is far shorter than that which would be needed to create a working laser.

Additionally, because the pump waveguide mode field P decays exponentially as it approaches the active gain region associated with the signal waveguide core 20, small variations of the coupling gap g through, for example, variations in the thickness of the spacer layer 50, can be translated into significant changes in the mode field overlap. For example, it is contemplated that, where the active gain region 25 comprises quantum wells characterized by a material absorption of approximately 1×10⁵ cm⁻¹ at the pump wavelength (as is the case for MQWs based on In_{0.25}Ga_{0.75}N), an optical coupling gap g between approximately 0.4 μm and approximately 0.8 μm or, more narrowly, between approximately 0.5 μm and approximately 0.6 μm, is likely to be suitable. It is contemplated that the coupling gap g does not have to be constant along the length of the optical signal axis 22. For example, in one embodiment, the coupling gap g decreases along the length of the optical signal axis 22 to help to improve pumping uniformity. More specifically, the coupling gap g decreases along the length of the optical signal axis 22 at a rate that is sufficient to compensate for depletion of the propagating pumping light as it is absorbed by the active gain region.

In FIG. 6, the refractive index n of the pump waveguide core 10 is less than, approximately equal to, or otherwise not substantially greater than the refractive index n of the signal waveguide core 20, at the pump wavelength λ. As will be appreciated by those familiar with the optical physics, if the mode index of the pump waveguide is below the refractive index of the associated the signal waveguide at the pump wavelength, then the pump mode intensity can exhibit one or more peaks in the signal waveguide. Accordingly, the pump waveguide core 10, the signal waveguide core 20, and the associated cladding materials can be configured such that at least part of a frustrated portion of the pump waveguide mode field P′ extends into the active gain region associated with the signal waveguide core 20. For the purposes of defining and describing the present invention, it is noted that a mode field comprising a frustrated portion is characterized by a major intensity peak and a minor intensity peak that lies along the decayed intensity portion of the mode field. The minor intensity peak is referred to herein as the frustrated portion of the mode field. For example, in FIG. 6, the pump waveguide mode field P′ comprises a major intensity peak that lies outside of the active gain region associated with the signal waveguide core 20 and a frustrated portion, most of which lies inside the active gain region associated with the signal waveguide core 20. The frustrated portion is at least one, preferably between one and two, orders of magnitude less than the intensity maximum that lies outside of the active gain region.

As is illustrated in FIGS. 5 and 6, regardless of whether the pump waveguide mode field P, P′ is presented as an ordinary decayed field or a mode field comprising a frustrated portion, the optical signal propagating along the longitudinal optical signal axis 22 will be characterized by a signal waveguide mode field S, S′ that comprises an intensity maximum inside the active gain region associated with the signal waveguide core 20. In this manner, the concepts of the present disclosure may be employed to optimize optical pumping and ensure high modal gain in the active region.

Referring to FIG. 1, in one contemplated embodiment, the active gain region 25 comprises InGaN based MQWs and is configured for blue pumped emission in the green portion of the optical spectrum. The spacer layer 50 and the cladding layer 60, which displace the pump waveguide core 10 from the signal waveguide core 20, comprise GaN, AlGaN, or InGaN. The pump waveguide core 10 comprises a TiO₂ waveguide medium, the signal waveguide core 20 comprises GaN or InGaN, and the cap layer 40 comprises Ta₂O₅. The remaining cladding layer 62 is optional and comprises AlGaN. The device substrate 60 comprises GaN. To facilitate efficient pumping, it is contemplated that the laser source 100 may be provided with an input mirror that is reflective in the green portion of the optical spectrum and transmissive in the blue portion of the optical spectrum. Further, an output mirror that is transmissive in the green portion of the optical spectrum and reflective in the blue portion of the optical spectrum may be provided in the event multiple pass pumping is desired. The pump waveguide core 10 may be constructed as a single or multi-mode waveguide.

It is noted that recitations herein of a component of the present disclosure being “configured” in a particular way, to embody a particular property, or to function in a particular manner, are structural recitations, as opposed to recitations of intended use. More specifically, the references herein to the manner in which a component is “configured” denotes an existing physical condition of the component and, as such, is to be taken as a definite recitation of the structural characteristics of the component.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the terms “substantially” and “approximately” are utilized herein to represent the inherent degree of uncertainty that may be attributed to any quantitative comparison, value, measurement, or other representation. The terms “substantially” and “approximately” are also utilized herein to represent the degree by which a quantitative representation may vary from a stated reference without resulting in a change in the basic function of the subject matter at issue. For example, reference is made herein to the refractive index of the pump waveguide core 10 as “not substantially greater than” the refractive index of the signal waveguide core 20, at the pump wavelength. For the purposes of describing and defining the present invention, it is noted that the term “substantially” should be taken to limit this language to pump waveguide core refractive index values that merely vary from the stated reference by a degree that would not alter the recited function of the pump waveguide core.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Rather, the claims appended hereto should be taken as the sole representation of the breadth of the present disclosure and the corresponding scope of the various inventions described herein. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects. For example, although the present disclosure only refers specifically to blue pumped green lasers, it is contemplated that the concepts disclosed herein will be applicable to any optically pumped laser structure where the active material absorption is too high for effective pumping by alternative means, e.g., end pumping or side pumping.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1. A laser comprising a pump waveguide core, a signal waveguide core, and an active gain region, wherein:
the pump waveguide core is oriented along a longitudinal optical pumping axis and is surrounded by cladding material characterized by an index of refraction that is lower than that of the pump waveguide core at a given pump wavelength;
the signal waveguide core is oriented along a longitudinal optical signal axis and is surrounded by cladding material characterized by an index of refraction that is lower than that of the signal waveguide core at a given signal wavelength;
the optical pumping axis is approximately parallel to the longitudinal optical signal axis and the pump waveguide core is displaced from the signal waveguide core by an optical coupling gap g in a lateral direction that is approximately perpendicular to the optical pumping axis; and
the signal waveguide core, the pump waveguide core, the surrounding cladding materials, and the optical coupling gap g are configured such that pump radiation propagating along the longitudinal optical pumping axis is characterized by a pump waveguide mode field comprising a decayed intensity portion, at least part of which extends into the active gain region to optically pump the active gain region and form an optical signal propagating along the longitudinal optical signal axis of the signal waveguide core.

2. A laser as claimed in claim 1 wherein the decayed intensity portion of the pump waveguide mode field comprises an exponentially decayed intensity portion.

3. A laser as claimed in claim 2 wherein the refractive index of the pump waveguide core is greater than the average refractive index of the signal waveguide core, at the pump wavelength.

4. A laser as claimed in claim 3 wherein the pump waveguide core comprises a TiO₂ waveguide medium and the signal waveguide core comprises GaN or InGaN.

5. A laser as claimed in claim 2 wherein the pump waveguide mode field comprises an intensity maximum that lies outside of the active gain region and a decayed intensity portion, at least part of which lies inside the active gain region.

6. A laser as claimed in claim 5 wherein the part of the decayed intensity portion that lies inside the active gain region is at least one order of magnitude less than the intensity maximum that lies outside of the active gain region.

7. A laser as claimed in claim 5 wherein the part of the decayed intensity portion that lies inside the active gain region is between approximately two and approximately four orders of magnitude less than the intensity maximum that lies outside of the active gain region.

8. A laser as claimed in claim 1 wherein the pump waveguide mode field comprises a frustrated portion, at least part of which extends into the active gain region.

9. A laser as claimed in claim 8 wherein the refractive index of the pump waveguide core is not substantially greater than the refractive index of the signal waveguide core, at the pump wavelength.

10. A laser as claimed in claim 8 wherein the refractive index of the pump waveguide core is less than or approximately equal to the refractive index of the signal waveguide core, at the pump wavelength.

11. A laser as claimed in claim 8 wherein the pump waveguide mode field is characterized by at least one major intensity peak that lies outside of the active gain region and at least one minor intensity peak, at least part of which lies inside the active gain region associated with the signal waveguide core.

12. A laser as claimed in claim 11 wherein a difference between the respective maxima of a major intensity peak lying outside of the active gain region and a minor intensity peak lying inside the active gain region is at least one order of magnitude.

13. A laser as claimed in claim 11 wherein a difference between the respective maxima of a major intensity peak lying outside of the active gain region and a minor intensity peak lying inside the active gain region is approximately two orders of magnitude.

14. A laser as claimed in claim 1 wherein:
the active gain region extends along the optical signal axis; and
the optical coupling gap g is sufficiently large to ensure that at least approximately 100 μm of the active gain region length is required for absorption of a majority of the pump waveguide mode field by the active gain region and is sufficiently small to ensure that the pump waveguide mode field overlaps the active gain region.

15. A laser as claimed in claim 1 wherein:
the active gain region comprises quantum wells characterized by a material absorption of approximately 1×10⁵ cm⁻¹ at the pump wavelength; and
the optical coupling gap g is between approximately 0.4 μm and approximately 0.8 μm.

16. A laser as claimed in claim 1 wherein:
the optical coupling gap g is less than approximately 10 μm.

17. A laser as claimed in claim 1 wherein:
the active gain region comprises InGaN quantum wells characterized by a material absorption of approximately 1×10⁵ cm⁻¹ at the pump wavelength; and
the optical coupling gap g is between approximately 0.5 μm and approximately 0.6 μm.

18. A laser as claimed in claim 1 wherein:
the pump waveguide mode field comprises a decayed intensity portion, at least part of which extends into the active gain region; and
the optical signal propagating along the longitudinal optical signal axis is characterized by a signal waveguide mode field comprising at least one intensity maximum that lies inside the signal waveguide core.

19. A laser as claimed in claim 1 wherein:
the pump radiation is electrically or optically generated in the pump waveguide core or is carried by the pump waveguide core; and
the active gain region is configured for blue pumped emission in the green portion of the optical spectrum.

20. A semiconductor laser comprising a pump waveguide core, a signal waveguide core, and a MQW active region, wherein:
the pump waveguide core is oriented along a longitudinal optical pumping axis and is surrounded by cladding material characterized by an index of refraction that is lower than that of the pump waveguide core at a given pump wavelength;
the signal waveguide core and the MQW active region are oriented along a longitudinal optical signal axis and are surrounded by cladding material characterized by an index of refraction that is lower than that of the signal waveguide core at a given signal wavelength;
the optical pumping axis is approximately parallel to the longitudinal optical signal axis and the pump waveguide core is displaced from the signal waveguide core by an optical coupling gap g in a lateral direction that is approximately perpendicular to the optical pumping axis; and
the signal waveguide core, the MQW active region, the pump waveguide core, the surrounding cladding materials, and the optical coupling gap g are configured such that
pump radiation propagating along the longitudinal optical pumping axis is characterized by a pump waveguide mode field that overlaps the MQW active region,
the MQW active region extends along the optical signal axis,
the optical coupling gap g is sufficiently large to ensure that at least approximately 100 μm of the MQW active region length is required for absorption of a majority of the pump waveguide mode field by the MQW active region and is sufficiently small to ensure that the pump waveguide mode field overlaps the MQW active region,
the optical coupling gap g is less than approximately 3 μm,
the pump radiation propagating along the longitudinal optical pumping axis stimulates emission of photons in the MQW active region to form an optical signal in the green portion of the optical spectrum propagating along the longitudinal optical signal axis, and
the optical signal propagating along the longitudinal optical signal axis is characterized by a signal waveguide mode field comprising at least one intensity maximum that lies inside the signal waveguide core.
